(19) United States
(12) Patent Application Publication
(10) Pub. No.: US 2024/0289603 A1
(43) Pub. Date: Aug. 29, 2024

(54) TRAINING A NEURAL NETWORK USING CONTRASTIVE SAMPLES FOR MACRO PLACEMENT

(71) Applicant: MediaTek Inc., Hsinchu City (TW)

(72) Inventors: Da-Shan SHIU, Hsinchu City (TW); Alexandru CIOBA, Cambridge (GB); Fu-Chieh CHANG, Hsinchu City (TW)

(21) Appl. No.: 18/042,439

(22) PCT Filed: Oct. 12, 2022
(86) PCT No.: PCT/CN2022/124856

§ 371 Date: Feb. 21, 2023

Related U.S. Application Data
(60) Provisional application No. 63/254,582, filed on Oct. 12, 2021.

(51) Int. Cl. G06N 3/08

(52) U.S. Cl. CPC G06N 3/08

(57) ABSTRACT

A system trains a neural network (NN) for macro placement. The system constructs a set of positive samples of trajectories by sequentially removing the same set of macros in different orders from an at least partially-placed canvas of a chip. The system also constructs a set of negative samples of trajectories by placing not-yet-placed macros at random positions on an at least partially-empty canvas of the chip. The system then trains the NN and a graph NN (GNN) in the NN using the positive samples and the negative samples.

### CROSS-REFERENCE TO RELATED APPLICATIONS

This application claims the benefit of U.S. Provisional Application No. 63/254,582 filed on Oct. 12, 2021, the entirety of which is incorporated by reference herein.

### TECHNICAL FIELD

Embodiments of the invention relate to methods and apparatuses based on machine learning and artificial intelligence (AI) for generating a macro placement on a semiconductor chip.

### BACKGROUND

In an integrated circuits (IC) design, a macro is a set of circuit components that can be viewed as a black box. The logic and electronic behavior of the macro are given but the internal structural description may or may not be known. Mixed-size macro placement is the problem of placing macros of various sizes on a chip canvas to optimize an objective such as the wirelength, congestion, etc.

Training an EDA tool to properly place macros often requires many placement samples. For supervised training, each sample is evaluated (“labeled”) based on various objectives. Such evaluations can be expensive in terms of computational time, resources, and licensing costs.

The labeling cost can be further exacerbated when one wants to collect samples that have a particular feature. For example, a designer may want to collect samples that have the problematic feature of “unusable area.” Because the probability of this problem happening is low, it requires a lot of sample generation to collect a sufficient amount of samples. Furthermore, it is time-consuming for labeling experts to sift through all those samples to identify those that contain a particular feature. Additionally, for every new type of feature, a designer often has to repeat the process of sample generation, identification, and labeling. It is difficult to integrate this process with online reinforcement learning.

Given the high cost of labeling placement samples, there is a need for improving the training methods for macro placement tools to minimize the labeling cost.

### SUMMARY

In one embodiment, a method is provided for training a neural network (NN) for macro placement. A set of positive samples of trajectories is constructed by sequentially removing a same set of macros in different orders from an at least partially-placed canvas of a chip. A set of negative samples of trajectories is constructed by placing not-yet-placed macros at random positions on an at least partially-empty canvas of the chip. Then the NN and a graph NN (GNN) in the NN are trained using the positive samples and the negative samples.

In another embodiment, a system is operative to train an NN for macro placement. The system includes processing hardware, and memory coupled to the processing hardware to store information on the NN, a set of chips, and macros placed on the chips. The processing hardware is operative to construct a set of positive samples of trajectories by sequentially removing a same set of macros in different orders from an at least partially-placed canvas of a chip, and construct a set of negative samples of trajectories by placing not-yet-placed macros at random positions on an at least partially-empty canvas of the chip. The processing hardware is further operative to train the NN and a GNN in the NN using the positive samples and the negative samples.

Other aspects and features will become apparent to those ordinarily skilled in the art upon review of the following description of specific embodiments in conjunction with the accompanying figures.

### BRIEF DESCRIPTION OF THE DRAWINGS

The present invention is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one. Further, when a particular feature, structure, or characteristic is described in connection with an embodiment, it is submitted that it is within the knowledge of one skilled in the art to effect such feature, structure, or characteristic in connection with other embodiments whether or not explicitly described.

FIG. 1 is a block diagram illustrating a neural network (NN) for macro placement according to one embodiment.

FIG. 2 illustrates a macro placement process according to one embodiment.

FIG. 3 is a flow diagram illustrating a method for training an NN using contrastive samples according to one embodiment.

FIG. 4 is a flow diagram illustrating positive sample construction according to one embodiment.

FIG. 5A is a flow diagram illustrating negative sample construction according to one embodiment.

FIG. 5B is a flow diagram illustrating negative sample construction according to another embodiment.

FIG. 6 is a flow diagram illustrating the representation pre-training in FIG. 3 according to one embodiment.

FIG. 7 is a flow diagram illustrating the fine-tuning in FIG. 3 according to one embodiment.

FIG. 8 is a flow diagram of a sample collection operation according to one embodiment.

FIG. 9 is a flow diagram of a fine-tuning training operation according to one embodiment.

FIG. 10 is a flow diagram of the evaluation operation according to one embodiment.

FIG. 11 illustrates an example of a system according to one embodiment.

FIG. 12 is a flow diagram illustrating a method for training an NN for macro placement according to one embodiment.

### DETAILED DESCRIPTION

In the following description, numerous specific details are set forth. However, it is understood that embodiments of the invention may be practiced without these specific details. In other instances, well-known circuits, structures, and techniques have not been shown in detail in order not to obscure the understanding of this description. It will be appreciated, however, by one skilled in the art, that the invention may be practiced without such specific details. Those of ordinary skill in the art, with the included descriptions, will be able to implement appropriate functionality without undue experimentation.

This disclosure provides tools for macro placement and methods for training the tools for macro placement using contrastive samples. One benefit of using contrastive samples is to minimize the cost of evaluating the final design objectives. According to an embodiment to be described herein, contrastive samples include positive samples and negative samples produced from a set of chips that already have macros placed thereon (i.e., placed chips). As used herein, a semiconductor chip is an integrated circuit block also referred to as a chip. A macro contains a set of integrated circuit components, and a chip canvas is a two-dimensional (2D) area on the chip where macros may be placed.

From a set [symbol] of known good placements (e.g., placements that satisfy a given objective), a positive sample pair (i.e., a pair consisting of two positive samples) can be constructed by entirely or partially removing placed macros from a chip in two different orders. In one embodiment, given a completed macro placement on a given chip, a positive sample can be constructed by removing one macro at a time to form a trajectory of (state, action) pairs until all of the macros are removed from the chip. From the same macro placement on the same chip, multiple positive samples can be constructed by removing the macros in different orders.

With respect to negative samples, a negative sample pair (i.e., a pair consisting of two negative samples) can be two random placements, which have a high probability of having different value functions. In one embodiment, given a macro placement on a chip, a negative sample can be constructed by randomly placing one macro at a time to an empty or partially-placed canvas of the chip to form a trajectory of (state, action) pairs until all of the macros are placed on the chip.

The collection of positive samples and negative samples may be used to train an AI agent, such as a neural network (NN). The NN learns to differentiate the positive samples from the negative samples. After the training, by transfer learning the NN can perform macro placement on chips that are not in the training set.

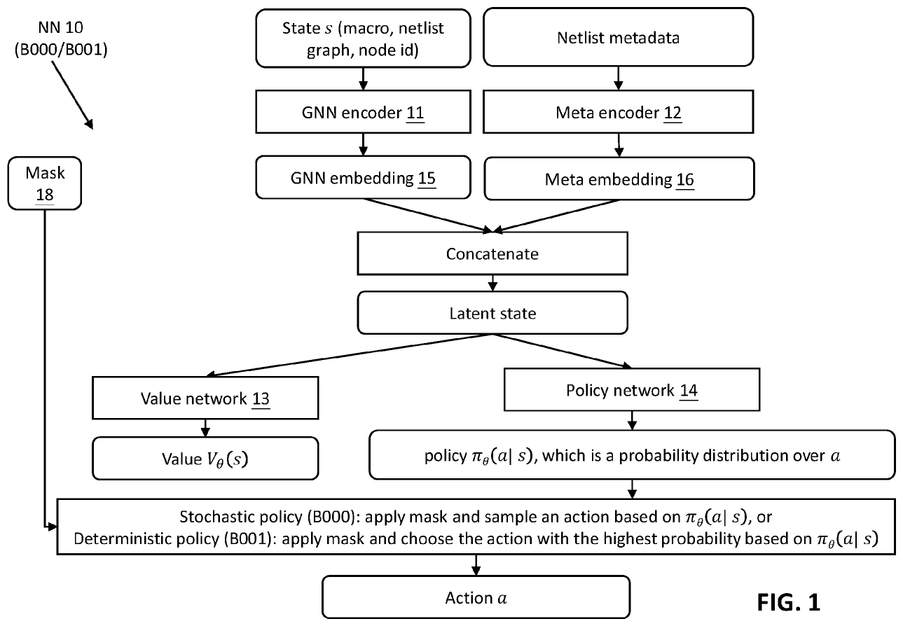

FIG. 1 is a block diagram illustrating an NN 10 for macro placement according to one embodiment. NN 10 receives inputs including state s (macro, netlist graph, node id) and netlist metadata. NN 10 encodes the state using a graph neural network (GNN) 11 into a low-dimension vector, referred to as a GNN embedding 15. NN 10 also encodes the netlist metadata using a meta encoder 12 into another low-dimension vector, referred to as a meta embedding 16. GNN embedding 15 and meta embedding 16 are concatenated into a latent state. This latent state is fed into a value network 13 and a policy network 14. Policy network 14 generates a policy π_{θ}(a|s), where π_{θ}(a|s) is a probability distribution of action a for a given state s. The action specifies a coordinate on the chip canvas for placing a macro. The state is the canvas including any macros placed thereon. Value network 13 generates a value that predicts the 20) reward of action a. NN 10 is parameterized by θ, which represents the set of parameters that defines NN 10. Based on policy π_{θ}(a|s), NN 10 applies a mask 18 on the chip canvas and generates an action as output. The action is generated based on policy πθ(a|s) as well as a stochastic policy or a deterministic policy. In this disclosure, NN 10 following the stochastic policy is referred to as B000, and NN 10 following the deterministic policy is referred to as B001. In some embodiments, NN 10 may be used for macro placement.

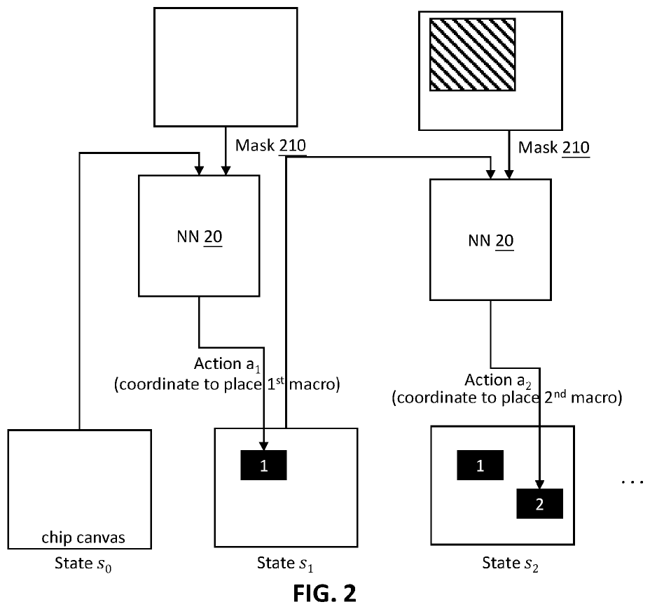

FIG. 2 illustrates a macro placement process according to one embodiment. Given a chip canvas and a trained NN 20, NN 20 performs an action a₁ to place a macro 1 on a first coordinate of the canvas. NN 20 may have the same network structure as NN 10 (FIG. 1). The state of the canvas at this point (after action a₁ is performed) is denoted as s₁. A mask 210 is updated to indicate the area surrounding macro 1 that is not to be occupied by the next macro. NN 20 then performs an action a₂ to place a macro 2 on a second coordinate of the canvas. The canvas state is updated to s₂, and mask 210 is also updated (not shown) to prevent subsequent macros from undesired overlapping with the first two macros. The chip placement process continues until all of the macros are placed on the chip canvas.

The chip placement process illustrated in FIG. 2 produces a trajectory of (state, action) pairs (s₁, a₁), . . . , (sₙ, aₙ) for placing n macros, where the final state sₙ denotes the chip canvas with completed macros placement. For a given state, NN 20 is trained to generate a probability distribution for a corresponding action. In one embodiment, NN 20 applies mask 210 to the probability distribution to produce a masked distribution over grid points on the chip canvas where an action can take place. With a deterministic policy, NN 20 chooses an action with the highest probability to place a macro according to the masked distribution. With a stochastic policy, NN 20 samples an action for placing a macro according to the masked distribution.

An example of a masked distribution is as follows. If the probability distribution generated by the policy network of NN 20 over 5 coordinates where actions can take place is:

| Action 1 | Action 2 | Action 3 | Action 4 | Action 5 |
|---|---|---|---|---|
| 0.2 | 0.3 | 0.1 | 0.1 | 0.3 |

Applying a mask that blocks out areas where actions 1, 2, and 4 can take place, this probability distribution becomes a masked distribution as follows:

| Action 1 | Action 2 | Action 3 | Action 4 | Action 5 |
|---|---|---|---|---|
| 0 | 0 | 0.1/(0.1 + | 0 | 0.3/(0.1 + |
| | | 0.3) = 0.25 | | 0.3) = 0.75 |

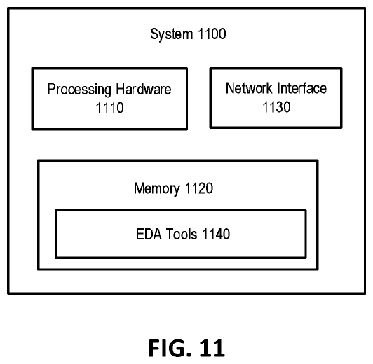

The following description discloses a number of methods with reference to flow diagrams. These methods may be performed by a computing system, such as a system 1100 in FIG. 11, on which a placement tool such as an NN is trained. Moreover, some of the methods in the following descriptions refer to the use of a “threshold.” It is understood that the thresholds in different methods/stages/operations/steps may refer to different numerical values.

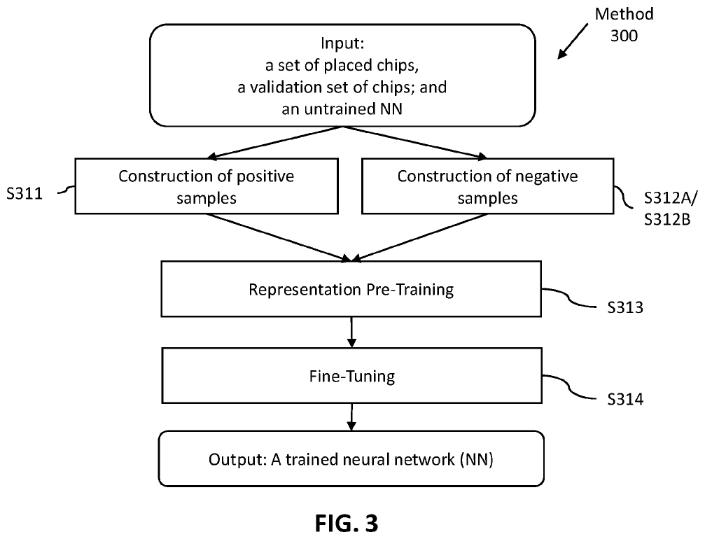

FIG. 3 is a flow diagram illustrating a method 300 for training an NN using contrastive samples according to one embodiment. The input to method 300 includes a set of chips having macros already placed thereon (i.e., placed chips), a validation set of chips, and an untrained NN. The set of placed chips may be used as a training set in fine-tuning (S314). Alternatively, an additional set of chips may be included in the input as a training set for fine-tuning (S314). Method 300 starts with constructing a set of positive samples (S311) and a set of negative samples (S312A or S312B). These samples are fed into the untrained NN for representation pre-training (S313) and fine-tuning (S314). The output of the fine-tuning is a trained NN.

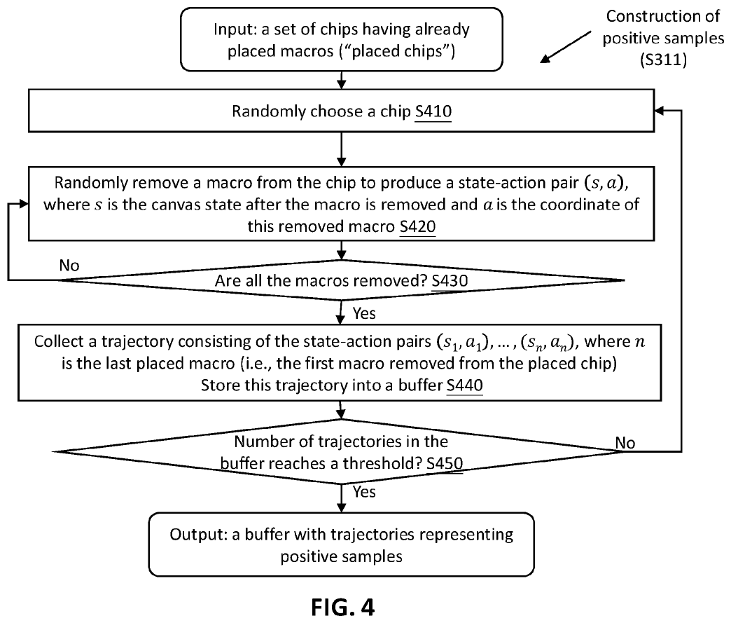

FIG. 4 is a flow diagram illustrating positive sample construction (S311) according to one embodiment. The input to S311 includes the set of chips having macros already placed thereon (i.e., placed chips). For each placed chip, the original macro placement order is known. S311 begins with the system randomly choosing a chip from the set of placed chips (S410). The system then randomly removes a macro from the chip to produce a state-action pair (s, a) (S420), where s is the canvas state after the macro is removed and a is the coordinate of this removed macro. In one embodiment, the system may create a pair of positive samples by removing the same set of macros from the same chip in two different random orders. In one embodiment, the system may create a positive sample by removing a first subset of macros from a chip in a predetermined order (e.g., in the reverse order to the original macro placement order) and a second subset of macros from the chip in a random order. When all of the macros are removed from the chip (S430), the system collects a trajectory consisting of the state-action pairs (s₁, a₁), . . . , (sₙ, aₙ) produced in S420, where n is the last placed macro (i.e., the first macro removed from the placed chip at S420), and stores this trajectory into a buffer (S440). When the number of trajectories in the buffer reaches a threshold (S450), the system outputs the buffer with trajectories representing positive samples.

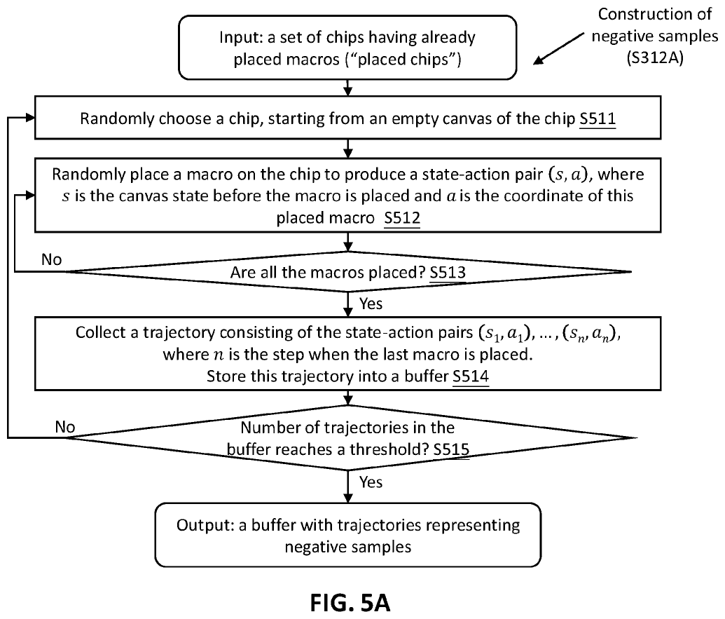

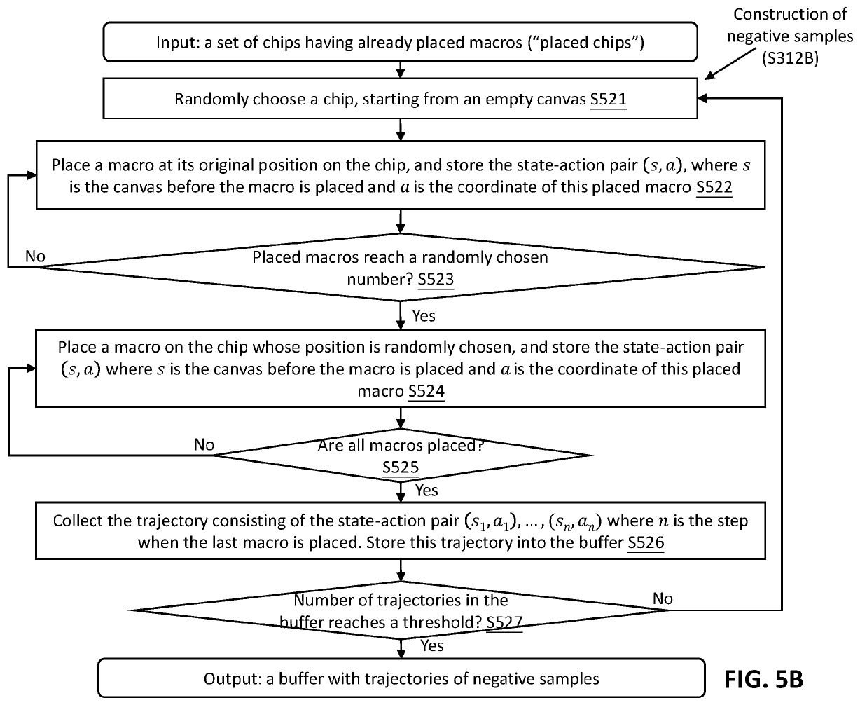

FIG. 5A is a flow diagram illustrating negative sample construction (S312A) in FIG. 3 according to one embodiment. The input to S312A includes the set of chips having macros already placed thereon. S312A begins with the system randomly choosing a chip from the set of placed chips (S511), starting with an empty canvas of the chip. The system then places a not-yet-placed macro on a randomly-chosen coordinate of the chip to produce a state-action pair (s, a) (S512), where s is the canvas state after the macro is placed and a is the coordinate of this placed macro. The system at S512 may randomly choose a macro for placement, or may follow the original placement order for choosing the macro. When all of the macros are placed on the chip (S513), the system collects a trajectory consisting of the state-action pairs (s₁, a₁), . . . , (sₙ, aₙ) produced in S512, where n is the number of macros, and stores this trajectory into a buffer (S514). When the number of trajectories in the buffer reaches a threshold (S515), the system outputs the buffer with trajectories representing negative samples.

FIG. 5B is a flow diagram illustrating negative sample construction (S312B) in FIG. 3 according to another embodiment. The input to S312B includes the set of chips having macros already placed thereon. S312B begins with the system randomly choosing a chip from the set of placed chips (S521), starting with an empty canvas of the chip. The system then places a randomly-chosen number of macros on the chip, with each macro placed at its original position on the chip (S522 and S523). This “original position” is the position of the macro on the placed chip in the input. The system at S522 may randomly choose a macro for placement, or may follow the original placement order for choosing the macro. Each placement of a macro creates a state-action pair (s, a) that the system stores in a buffer, where s is the canvas before the macro is placed and a is the coordinate of this placed macro. The system further places a not-yet-placed macro at a randomly-chosen position on the chip to produce an additional state-action pair (s, a), and stores this state-action pair in the buffer (S524). S524 is repeated until all of the macros are placed on the chip (S525). The system collects a trajectory consisting of the state-action pairs (s₁, a₁), . . . , (sₙ, aₙ) produced in S522 and S524, where n is the number of macros, and stores this trajectory into a buffer (S526). When the number of trajectories in the buffer reaches a threshold (S527), the system outputs the buffer with trajectories representing negative samples.

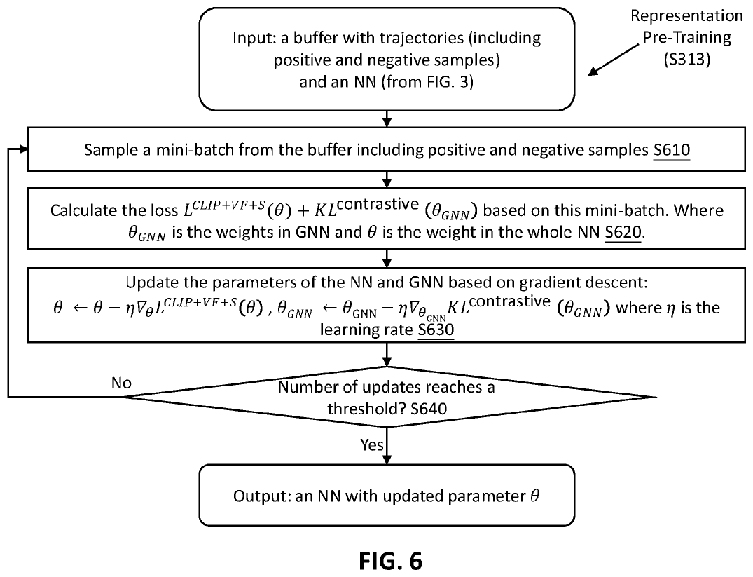

FIG. 6 is a flow diagram illustrating the representation pre-training (S313) in FIG. 3 according to one embodiment. The representation pre-training (S313) may be performed by a computing system to train the NN in the input of method 300 (FIG. 3). The system starts with sampling a mini-batch of trajectories from the buffer that contains positive and negative samples (S610). The system then calculates the loss L^{CLIP+VF+S}(θ)+KL_{contrastive} (θ_{GNN}) based on this mini-batch (S620), where θ_{GNN} IS the weights of the GNN (e.g., GNN encoder 11 in FIG. 1) and θ is the weights (i.e., parameter) of the whole NN (e.g., NN 10 in FIG. 1), where θ_{GNN}⊂θ. The system calculates the updated parameters of the NN θ and GNN θ_{GNN} based on gradient descent: θ←θ−η∇_{θ}L^{CLIP+VF+S}(θ), θ_{GNN}←θ_{GNN}−η∇_{θGNN}KL^{contrastive} (θ_{GNN}) where n is the learning rate and K is a multiplier chosen by a designer (S630). S610, S620, and S630 are repeated until the number of updates reaches a threshold (S640). The system outputs the NN with the updated parameter θ.

The mathematical formulation of the representation pre-training (S313) is provided below. Given a parametric model f_{θ} of GNN embedding 16 (FIG. 1), a contrastive loss L^{contrastive} can be calculated based on a distance measurement L₁ between positive sample pairs in [symbol] and between negative samples pairs in [symbol] as follows:

$${L}_{1} ( {x}_{1} , {x}_{2} , θ ) = 1 [ ( {x}_{1} , {x}_{2} ) ∈ 𝒫 ] {‖ {f}_{θ} ( {x}_{1} ) - {f}_{θ} ( {x}_{2} ) ‖}_{2}^{2} + 1 [ ( {x}_{1} , {x}_{2} ) ∈ 𝒩 ] {max ( 0 , ϵ - {‖ {f}_{θ} ( {x}_{1} ) - {f}_{θ} ( {x}_{2} ) ‖}_{2} )}^{2}$$

where (x₁, x₂) is a pair of positive samples when (x₁, x₂)∈ [symbol] , and (x₁, x₂) is a pair of negative samples when (x₁, x₂)∈ [symbol] .

When multiple negative pairs (x, xᵢ⁻)_{i=1,N} are created from a single true sample x (i.e., the original trajectory of a placed chip in the input set) along with one positive pair (x, x⁺), another contrastive loss L^{contrastive} can be calculated based on a similarity measurement L₂ as follows:

$${L}_{2} ( x , {x}^{+} , {( {x}_{i}^{-} )}_{i = 1 , N} ) = - log \frac{exp ( {{f}_{θ} ( x )}^{T} {f}_{θ} ( {x}^{+} ) )}{exp ( {{f}_{θ} ( x )}^{T} {f}_{θ} ( {x}^{+} ) ) + {\sum }_{i = 1}^{N} exp ( {{f}_{θ} ( x )}^{T} {f}_{θ} ( {x}_{i}^{-} ) )}$$

The NN parameter θ update can be calculated using a Proximal Policy Optimization (PPO) gradient estimator with generalized advantage estimation. The loss function (L^{CLIP+VF+S}) is described in equation (9) of “Proximal policy optimization algorithms, Schulman et al, arXiv preprint arXiv: 1707.06347 (2017).

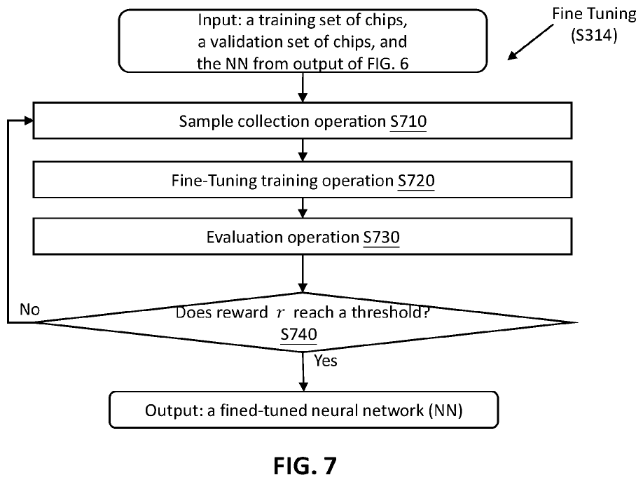

Referring back to FIG. 3, after the representation pre-training (S313), method 300 proceeds to fine-tuning (S314). The details of the fine-tuning (S314) are described below with reference to FIG. 7-FIG. 10.

FIG. 7 is a flow diagram illustrating the fine-tuning (S314) in FIG. 3 according to one embodiment. The input to S314 includes a training set of chips, a validation set of chips, and the NN in the output of FIG. 6. The training set of chips may or may not be the same as the placed chips in FIG. 3. The fine-tuning (S314) includes three operations: a sample collection operation (S710), a fine-tuning training operation (S720), and an evaluation operation (S730). S710, S720, and S730 are repeated until a reward r output from S730 reaches a predetermined threshold (S740). An example of the reward may be an objective, such as the wirelength or another design metric. At this point, the fine-tuning is completed and the output is a fine-tuned NN for macro placement.

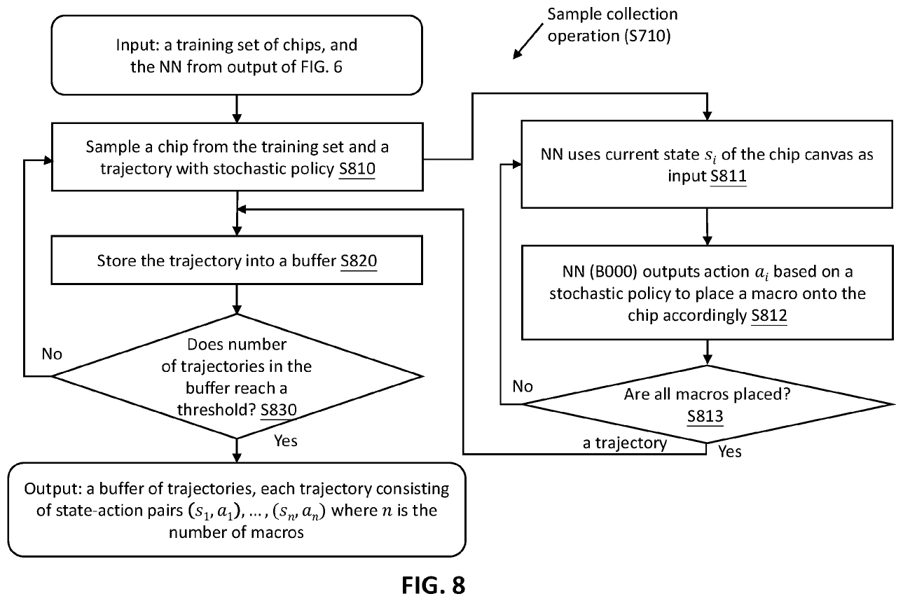

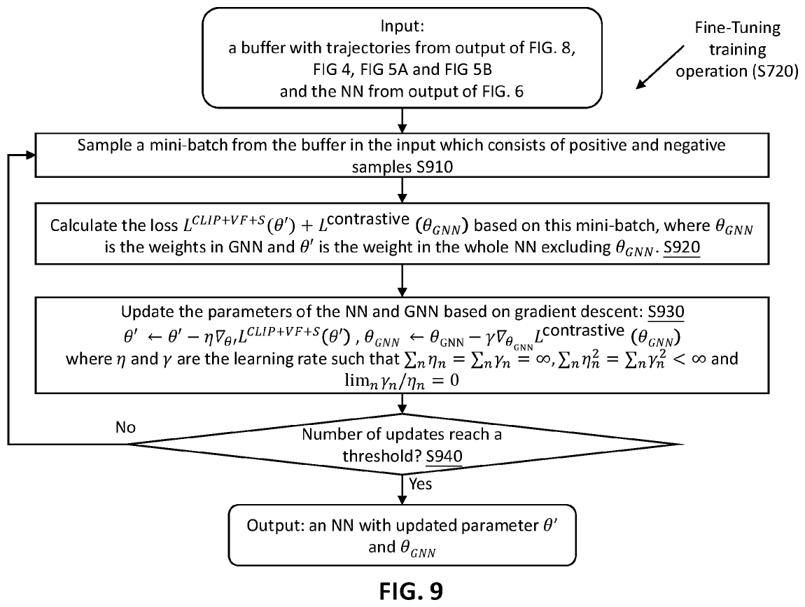

FIG. 8 is a flow diagram of the sample collection operation (S710) according to one embodiment. In the sample collection operation, the NN samples a chip from the training set and samples (i.e., generates) a trajectory with the stochastic policy (S810). The stochastic policy is described with reference to network B000 in FIG. 1. To generate a trajectory, the NN uses the current state sᵢ of the chip canvas as input (S811). The NN samples action aᵢ according to a probability distribution (generated by the NN) based on the stochastic policy (S812). The sampled action specifies a position on the sampled chip to place a macro. S811 and S812 are repeated until all of the macros are placed (S813), and a trajectory is formed by the sequence of (state, action) pairs. The trajectory is then stored in a buffer (S820). When the number of trajectories in the buffer reaches a threshold (S830), the buffer is provided as input to the fine-tuning training operation (S720) illustrated in FIG. 9.

FIG. 9 is a flow diagram of the fine-tuning training operation (S720) according to one embodiment. The fine-tuning training operation (S720) may be performed by a computing system, such as the system 1100 in FIG. 11, using the buffer generated in the sample collection operation (S710), as well as the buffer in the construction of positive samples (S311) and negative samples (S312A/S312B). The fine-tuning training operation begins with the system sampling a mini-batch of trajectories from the buffer (S910). The system calculates the loss L^{CLIP+VF+S}(θ′)+L^{contrastive} (θ_{GNN}) based on this mini-batch, where θ_{GNN} is the weights in GNN (e.g., the GNN encoder 11 in FIG. 1) and θ′ is the weights in the whole NN excluding θ_{GNN} (S920). The system updates the parameters of the NN θ and GNN θ_{GNN} based on gradient descent (S930): θ′←θ′−η∇_{θ},L^{CLIP+VF+S} (θ′), θ_{GNN}←θ_{GNN}−γ∇_{θGNN}L^{contrastive} (θ_{GNN}), where η and γ are the learning rate such that Σₙηₙ=Σₙγₙ=∞, Σₙηₙ²=Σₙγₙ²<∞ and limₙγₙ/ηₙ=0. S910, S920, and S930 are repeated until the number of updates reaches a predetermined threshold (S940). When the predetermined threshold is reached, the NN has the updated parameter θ′ and θ_{GNN}.

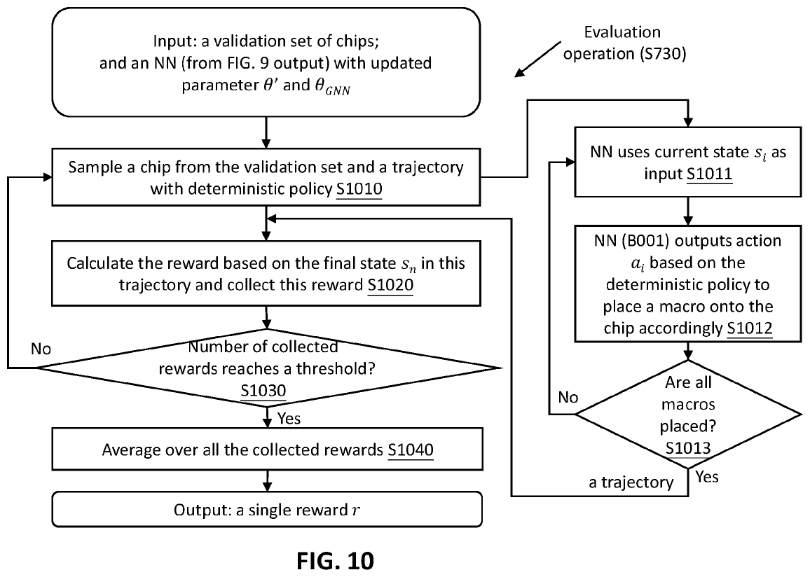

FIG. 10 is a flow diagram of the evaluation operation (S730) according to one embodiment. The input to the evaluation operation (S730) includes the validation set of chips (in the input of FIG. 3), and the NN with updated parameter θ′ and θ_{GNN} (in the output of FIG. 9). The evaluation operation (S730) begins with the NN samples a chip in the validation set and samples (i.e., generates) a trajectory with the deterministic policy (S1010). The deterministic policy is described with reference to network B001 in 30 FIG. 1. To generate a trajectory, the NN uses the current state sᵢ as input (S1011). The NN chooses an action aᵢ that has the highest probability according to a probability distribution (generated by the NN) based on the deterministic policy (S1012). The chosen action specifies a position on the sampled chip to place a macro. S1011 and S1012 are repeated until all of the macros are placed (S1013), and a trajectory is formed by the sequence of (state, action) pairs. The NN proceeds to calculate a reward r based on the final state Sₙ in this trajectory and collect this reward (S1030). S1010, S1020 (including S1011-S1012), and S1030 are repeated until the number of collected rewards has reached a predetermined threshold. The NN then averages over all the collected rewards (S1040) and outputs a single reward value.

Referring back to FIG. 7, after the evaluation operation (S730), the single reward value is compared 40) with a threshold (S740). The operations S710, S720, and S730 are repeated until the single reward value output from the evaluation operation (S730) reaches the threshold. At this point, the NN is fine-tuned. The fine-tuned NN may be given a new chip and macros to be placed on this new chip.

The rationale for contrastive sample construction is as follows. Given an optimal policy π* (i.e., the policy which can obtain the best placement given a chip), ŝ is a completion of a state s if ŝ is obtained by running the policy π* on s until episode termination (i.e., completion of placement). Two states s and s′ are equivalent s≃s′, if: (1) they are compatible, i.e., all macros that have been placed in both s and s′ share the same positions; and (2) they share a completion, i.e., ŝ=ŝ′. Then it follows that states V*(s)=V*(s′) and for any macro m which has not been placed in either s or s′, π*(s, m)=π*(s′, m). The methods disclosed herein are provided such that equivalent states share a similar representation.

Negative sample pairs may be mined by deliberately producing alterations to the samples of good known placements in such a way as to make the placement suboptimal. For example, a negative sample pair can be extracted from a partial placement of the original good placement and a partial placement of the subsequent bad placement.

During representation pre-training (S313) in FIG. 6, a contrastive loss is computed on equivalent states and non-equivalent states in order to pre-train the GNN representations.

Further explanation on contrastive loss is provided as follows. The contrastive loss is used during GNN representation pretraining (FIG. 6), after which the bias in the GNN weights is re-trained at fine-tuning time. With respect to the value function (calculated by value network 13 in FIG. 1), the system only directly inputs the canvas state and not the index of the next macro (i.e., node id) to the GNN in FIG. 6 in order to enforce the required bias in the value function regression. This way, the value function output is not affected by the next macro to be placed.

During representation pre-training (FIG. 6), the entire NN is trained on L^{CLIP+VF+S}(θ)+KL^{contrastive} (θ_{GNN}), where K is a multiplier tuned by the experimenter. Note that θ_{GNN}⊂θ so the above optimization is not decoupled.

During fine-tuning training operation (FIG. 9), the GNN parameters are set on an update-scale rule separate from the rest of the NN to preserve the bias acquired in pretraining. Namely, at the fine-tuning time, L_{CLIP+VF+S}(θ′)+L^{contrastive} (θ_{GNN}) is optimized with a learning rate schedule: γₙ for θ_{GNN} and ηₙ for all other parameters θ′ such that Σⁿ ηₙ=Σₙγₙ=∞, Σₙηₙ²=Σₙγₙ²<∞ and limₙγₙ/ηₙ=0.

FIG. 11 illustrates an example of a system 1100 according to one embodiment. System 1100 includes processing hardware 1110, a memory 1120, and a network interface 1130. In one embodiment, processing hardware 1110 may include one or more processors and accelerators, such as one or more of: a central processing unit (CPU), a GPU, a digital processing unit (DSP), an AI processor, a tensor processor, a neural processor, a multimedia processor, other general-purpose and/or special-purpose 25 processing circuitry.

System 1100 further includes the memory 1120 coupled to processing hardware 1110. Memory 1120 may include memory devices such as dynamic random access memory (DRAM), SRAM, flash memory, and other non-transitory machine-readable storage media; e.g., volatile or non-volatile memory devices. Memory 1120 may further include storage devices, for example, any type of solid-state or magnetic storage device. In one embodiment, memory 1120 may store one or more EDA tools 1140 including but not limited to neural networks, AI agents, and other tools for macro placement. Examples of EDA tools 1140 include B000 and B001 (FIG. 1). Memory 1120 may further stores information on a set of placed chip for construction of positive and negative samples, a training set of chips, a validation set of chips, and macros placed or to be placed on these chips. In some embodiments, memory 1120 may store instructions which, when executed by processing hardware 1110, cause the processing hardware to perform the aforementioned methods and operations for macro placement and/or for training an NN to perform macro placement. However, it should be understood that the aforementioned methods and operations can be performed by embodiments other than the embodiments of B000 and B001 (FIG. 1).

In some embodiments, system 1100 may also include a network interface 1130 to connect to a wired and/or wireless network. It is understood the embodiment of FIG. 11 is simplified for illustration purposes. Additional hardware components may be included.

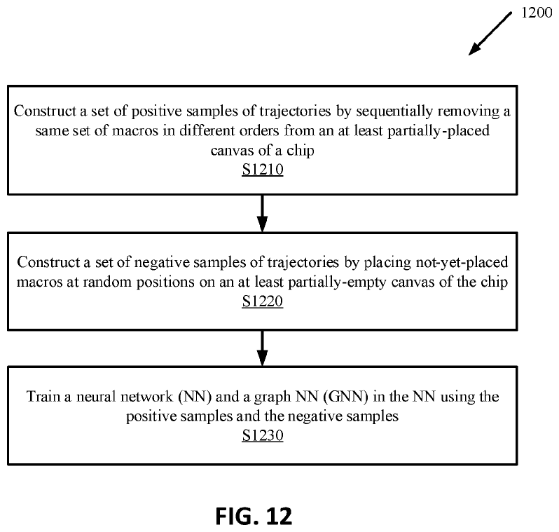

FIG. 12 is a flow diagram illustrating a method 1200 for training an NN for macro placement according to one embodiment. In one embodiment, method 1200 may be performed by the system 1100 in FIG. 11. Method 1200 begins with the system constructing a set of positive samples of trajectories by sequentially removing a same set of macros in different orders from an at least partially-placed canvas of a chip (S1210). The at least partially-placed canvas may be completely placed or partially placed. The system also constructs a set of negative samples of trajectories by placing not-yet-placed macros at random positions on an at least partially-empty canvas of the chip (S1220). The at least partially-empty canvas may be entirely or partially empty. The system then trains the NN and a GNN in the NN using the positive samples and the negative samples (S1230).

In one embodiment, each positive sample is a trajectory of (state, action) pairs, where the state is a canvas state after a macro is removed and the action is a coordinate of the macro. At least one of the positive samples may be constructed by sequentially removing all macros from the chip in a random order. At least one of the positive samples may be constructed by sequentially removing a first subset of the macros in the same set from the chip in a predetermined order and a second subset of the macros in the same set from the chip in a random order.

In one embodiment, each negative sample is a trajectory of (state, action) pairs, where the state is a canvas state before a macro is placed and the action is a coordinate of the macro. At least one of the negative samples may be constructed by sequentially placing all macros at random positions on an empty canvas of the chip. At least one of the negative samples may be constructed by sequentially placing a first subset of the macros in the same set on the chip at predetermined positions and a second subset of the macros in the same set on the chip at random positions. At least one of the negative samples may be constructed by placing the not-yet-placed macros in a random placement order.

In one embodiment, the GNN is trained based on a contrastive loss function that measures distances between a pair of positive samples and between a pair of negative samples. In one embodiment, the GNN is trained based on a contrastive loss function that measures the similarity between a true sample and a positive sample and between the true sample and one or more negative samples. The true sample is an original trajectory of the completed macro placement.

In one embodiment, training the NN includes pre-training the NN using the positive samples and the negative samples; and fine-tuning the NN using the positive samples, the negative samples, and trajectories generated from the pre-trained NN. Pre-training the NN may include updating parameters of the GNN based on a contrastive loss function calculated from the positive samples and the negative samples, and updating parameters of the NN including the GNN based on a loss function different from the contrastive loss function. Fine-tuning the NN may include updating parameters of the GNN based on a contrastive loss function calculated from the positive samples and the negative samples, and updating parameters of the NN excluding the GNN based on a loss function different from the contrastive loss function. Fine-tuning the NN may further include updating parameters of the NN excluding the GNN based on gradient descent with a first learning rate, and updating parameters of the GNN based on the gradient descent with a second learning rate different from the first learning rate. Fine-tuning the NN may further include the NN generating a first set of trajectories for updating NN parameters, each trajectory in the first set including an action that is sampled stochastically according to a probability distribution, the action indicating a coordinate on a chip canvas to place a macro. The NN further generates a second set of trajectories for evaluating the updated NN parameters, each trajectory in the second set including another action that is chosen according to another probability distribution as having a highest probability.

Various functional components or blocks have been described herein. As will be appreciated by persons skilled in the art, the functional blocks will preferably be implemented through circuits (either dedicated circuits, or general-purpose circuits, which operate under the control of one or more processors and coded instructions), which will typically comprise transistors that are configured in such a way as to control the operation of the circuitry in accordance with the functions and operations described herein.

While the invention has been described in terms of several embodiments, those skilled in the art will recognize that the invention is not limited to the embodiments described, and can be practiced with modification and alteration within the spirit and scope of the appended claims. The description is thus to be regarded as illustrative instead of limiting.

What is claimed is:

1. A method for training a neural network (NN) for macro placement, comprising:
constructing a set of positive samples of trajectories by sequentially removing a same set of macros in different orders from an at least partially-placed canvas of a chip;
constructing a set of negative samples of trajectories by placing not-yet-placed macros at random positions on an at least partially-empty canvas of the chip; and
training the NN and a graph NN (GNN) in the NN using the positive samples and the negative samples.

2. The method of claim 1, wherein each positive sample is a trajectory of (state, action) pairs, the state is a canvas state after a macro is removed and the action is a coordinate of the macro.

3. The method of claim 1, wherein at least one of the positive samples is constructed by sequentially removing all macros from the chip in a random order.

4. The method of claim 1, wherein at least one of the positive samples is constructed by sequentially removing a first subset of the macros in the same set from the chip in a predetermined order and a second subset of the macros in the same set from the chip in a random order.

5. The method of claim 1, wherein each negative sample is a trajectory of (state, action) pairs, the state is a canvas state before a macro is placed and the action is a coordinate of the macro.

6. The method of claim 1, wherein at least one of the negative samples is constructed by sequentially placing all macros at random positions on an empty canvas of the chip.

7. The method of claim 1, wherein at least one of the negative samples is constructed by sequentially placing a first subset of the macros in the same set on the chip at predetermined positions and a second subset of the macros in the same set on the chip at random positions.

8. The method of claim 1, wherein at least one of the negative samples is constructed by placing the not-yet-placed macros in a random placement order.

9. The method of claim 1, wherein the GNN is trained based on a contrastive loss function that measures distances between a pair of positive samples and between a pair of negative samples.

10. The method of claim 1, wherein the GNN is trained based on a contrastive loss function that measures similarity between a true sample and a positive sample and between the true sample and one or more negative samples, and wherein the true sample is an original trajectory of the completed macro placement.

11. The method of claim 1, wherein training the NN comprises:
pre-training the NN using the positive samples and the negative samples; and
fine-tuning the NN using the positive samples, the negative samples, and trajectories generated from the pre-trained NN.

12. The method of claim 11, wherein pre-training the NN further comprises:
updating parameters of the GNN based on a contrastive loss function calculated from the positive samples and the negative samples; and
updating parameters of the NN including the GNN based on a loss function different from the contrastive loss function.

13. The method of claim 11, wherein fine-tuning the NN further comprises:
updating parameters of the GNN based on a contrastive loss function calculated from the positive samples and the negative samples; and
updating parameters of the NN excluding the GNN based on a loss function different from the contrastive loss function.

14. The method of claim 11, wherein fine-tuning the NN further comprises:
updating parameters of the NN excluding the GNN based on gradient descent with a first learning rate; and
updating parameters of the GNN based on the gradient descent with a second learning rate different from the first learning rate.

15. The method of claim 11, wherein fine-tuning the NN further comprises:
generating, by the NN, a first set of trajectories for updating NN parameters, wherein each trajectory in the first set includes an action that is sampled stochastically according to a probability distribution, the action indicating a coordinate on a chip canvas to place a macro; and
generating, by the NN, a second set of trajectories for evaluating the updated NN parameters, wherein each trajectory in the second set includes another action that is chosen according to another probability distribution as having a highest probability.

16. A system operative to train a neural network (NN) for macro placement comprising:
processing hardware; and
memory coupled to the processing hardware to store information on the NN, a set of chips, and macros placed on the chips, wherein the processing hardware is operative to:
construct a set of positive samples of trajectories by sequentially removing a same set of macros in different orders from an at least partially-placed canvas of a chip;
construct a set of negative samples of trajectories by placing not-yet-placed macros at random positions on an at least partially-empty canvas of the chip; and
train the NN and a graph NN (GNN) in the NN using the positive samples and the negative samples.

17. The system of claim 16, wherein the processing hardware is further operative to remove all or a subset of the macros from the chip in a random sequential order when constructing at least one of the positive samples.

18. The system of claim 16, wherein the processing hardware is further operative to sequentially place all or a subset of the macros at random positions on the chip when constructing at least one of the negative samples.

19. The system of claim 16, wherein the processing hardware is further operative to sequentially place all or a subset of the macros in a random placement order on the chip when constructing at least one of the negative samples.

20. The system of claim 16, wherein the processing hardware is further operative to update parameters of the GNN based on a contrastive loss function calculated from the positive samples and the negative samples.
